(19) United States
(12) Patent Application Publication
(10) Pub. No.: US 2025/0089342 A1
(43) Pub. Date: Mar. 13, 2025

(54) SEMICONDUCTOR DEVICE AND METHOD FOR MANUFACTURING SEMICONDUCTOR DEVICE

(71) Applicant: Kioxia Corporation, Tokyo (JP)

(72) Inventors: Daichi NISHIKAWA, Mie (JP); Daisuke IKENO, Inuyama (JP); Junichi HAMAGUCHI, Kuwana (JP); Yoshiki SAITO, Yokkaichi (JP); Akihiro KAJITA, Yokohama (JP)

(73) Assignee: Kioxia Corporation, Tokyo (JP)

(21) Appl. No.: 18/822,592

(22) Filed: Sep. 3, 2024

(30) Foreign Application Priority Data
Sep. 8, 2023 (JP) 2023-146093

(51) Int. Cl. H01L 29/49; H01L 21/28

(52) U.S. Cl. CPC H10D 64/668; H01L 21/28052

(57) ABSTRACT

A semiconductor device of an embodiment includes: first and second regions that are provided in a substrate, the first and second regions containing impurities of a first conductivity type; a gate electrode disposed above the substrate between the first and second regions; first and second metal silicide layers disposed in the first and second regions, respectively; and first and second contacts connected to the first and second regions via the first and second metal silicide layers, respectively, in which the first and second contacts include: first and second oxidized silicide layers that are disposed at lower end portions of the first and second contacts and contain a predetermined metal different from metals included in the first and second metal silicide layers, respective; and metal layers that are in contact with the first and second oxidized silicide layers and extend in a second direction that intersects the first direction, respectively.

### CROSS-REFERENCE TO RELATED APPLICATIONS

This application is based upon and claims the benefit of priority from Japanese Patent Application No. 2023-146093, filed on Sep. 8, 2023; the entire contents of which are incorporated herein by reference.

### FIELD

Embodiments described herein relate generally to a semiconductor device and a method for manufacturing the semiconductor device.

### BACKGROUND

In order to operate a transistor included in a semiconductor device at high speed, a technique has been studied of connecting a contact for transmitting a control signal to the transistor to a source/drain region via, for example, a silicide layer. During manufacturing of the semiconductor device, a surface of the silicide layer may be naturally oxidized, which may increase contact resistance.

Thus, for example, by forming a barrier metal layer such as a titanium nitride layer, it is possible to reduce influence of a natural oxide layer on the surface of the silicide layer. However, a volume of a metal layer with a low resistance that serves as a core material of the contact is reduced by a volume occupied by the barrier metal layer with a high resistance.

### BRIEF DESCRIPTION OF THE DRAWINGS

FIG. 1 is a cross-sectional view illustrating an example of a configuration of a semiconductor device according to an embodiment;

FIGS. 2A to 2H are cross-sectional views sequentially exemplifying a part of a procedure of a method for manufacturing the semiconductor device according to an embodiment;

FIGS. 3A to 3F are cross-sectional views sequentially exemplifying a part of the procedure of the method for manufacturing the semiconductor device according to the embodiment;

FIGS. 4A to 4F are diagrams illustrating an example of a procedure of a method for forming an oxidized silicide layer included in the semiconductor device according to the embodiment;

FIG. 5 is a cross-sectional view illustrating an example of a semiconductor device to which a transistor according to the embodiment is applied; and

FIG. 6 is a cross-sectional view illustrating an example of another semiconductor device to which the transistor according to the embodiment is applied.

### DETAILED DESCRIPTION

A semiconductor device of an embodiment includes: first and second regions that are provided in a substrate and disposed apart from each other in a first direction that extends along the substrate, the first and second regions containing impurities of a first conductivity type; a gate electrode disposed above the substrate between the first and second regions; first and second metal silicide layers disposed in the first and second regions, respectively; and first and second contacts connected to the first and second regions via the first and second metal silicide layers, respectively, in which the first and second contacts include: first and second oxidized silicide layers that are disposed at lower end portions of the first and second contacts and contain a predetermined metal different from metals included in the first and second metal silicide layers, respectively; and metal layers that are in contact with the first and second oxidized silicide layers and extend in a second direction that intersects the first direction, respectively.

Hereinafter, embodiments of the present invention will be described in detail with reference to the drawings. Note that the present invention is not limited by the following embodiments. In addition, constituent elements in the following embodiments include those that can be easily assumed by those skilled in the art or those that are substantially the same.

### (Configuration Example of Semiconductor Device)

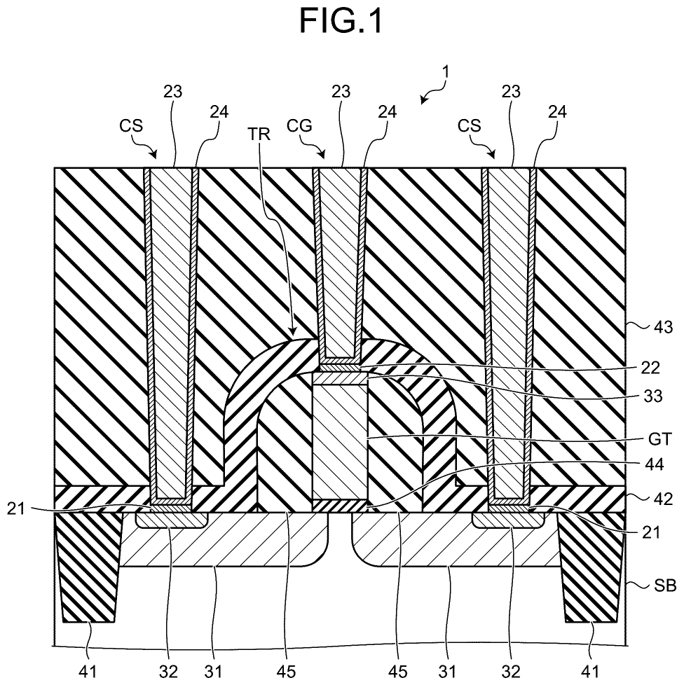

FIG. 1 is a cross-sectional view illustrating an example of a configuration of a semiconductor device 1 according to an embodiment. The semiconductor device 1 includes a semiconductor substrate SB, a transistor TR, and contacts CG and CS. The transistor TR is configured as a complementary metal-oxide-semiconductor (CMOS) or the like including a gate electrode GT and source/drain regions 31 provided on the semiconductor substrate SB.

The semiconductor substrate SB is, for example, a silicon substrate or the like, and is partitioned by element isolation layers 41. The element isolation layers 41 are formed by embedding silicon oxide layers or the like in the semiconductor substrate SB. The transistor TR is disposed in a region partitioned by the element isolation layers 41.

In the region partitioned by the element isolation layers 41, the source/drain regions 31 are provided at a predetermined distance from each other on the semiconductor substrate SB. In the source/drain regions 31 as first and second regions, impurities of a predetermined conductivity type are diffused. Silicide layers 32 are disposed on partial regions of the source/drain regions 31, respectively.

The silicide layers 32 as the first and second metal silicide layers are, for example, NiPtSi layers containing Ni and Pt as metals, or the like.

The gate electrode GT is disposed in a region between the source/drain regions 31 on the semiconductor substrate SB with a gate insulating layer 44 interposed therebetween. The gate electrode GT is, for example, a polysilicon layer or the like, and the gate insulating layer 44 is, for example, a silicon oxide layer or the like. A silicide layer 33 is disposed on the gate electrode GT.

However, the gate electrode GT may be, for example, a metal layer containing at least one of titanium (Ti), titanium nitride (TiN), tantalum (Ta), tantalum nitride (TaN), lanthanum (La), aluminum (Al), or titanium aluminum (AlTi). In addition, the gate insulating layer 44 may be, for example, a High-k insulating layer containing at least one of hafnium oxide and zirconium oxide.

The silicide layer 33 as a third metal silicide layer is also, for example, a NiPtSi layer containing Ni and Pt as metals, or the like. The silicide layer 33 may be included in a part of the gate electrode GT.

Side surfaces of the gate electrode GT and the silicide layer 33 are covered with spacer layers 45 that are silicon oxide layers or the like. In addition, a surface of the semiconductor substrate SB including the source/drain regions 31 and the element isolation layers 41, and the gate electrode GT, the silicide layer 33, and the spacer layers 45 are covered with a liner layer 42. The liner layer 42 is a silicon nitride layer, a silicon oxynitride layer, or the like. The liner layer 42 may have a configuration in which multiple silicon nitride layers or silicon oxynitride layers, and silicon oxide layers are stacked.

An insulating layer 43 such as a silicon oxide layer that covers these components is disposed above the liner layer 42.

The contact CG as a third contact penetrates the insulating layer 43 and the liner layer 42 and is connected to the gate electrode GT via the silicide layer 33. The contact CG includes a conductive layer 23 that serves as a core material of the contact CG, a conductive layer 24 that covers a side surface and a bottom surface of the conductive layer 23, and an oxidized silicide layer 22 disposed at a lower end portion of the conductive layer 24. As described above, the conductive layer 24 of the contact CG covers the conductive layer 23 and is in direct contact with the insulating layer 43.

The contacts CS as the first and second contacts penetrate the insulating layer 43 and the liner layer 42 and are connected to the source/drain regions 31 via the silicide layers 32. Each contact CS includes the conductive layer 23 that serves as a core material of the contact CS, the conductive layer 24 that covers a side surface and a bottom surface of the conductive layer 23, and an oxidized silicide layer 21 disposed at a lower end portion of the conductive layer 24. As described above, the conductive layer 24 of the contact CS also covers the conductive layer 23 and is in direct contact with the insulating layer 43.

As described later, the conductive layer 23 included in the contacts CG and CS is, for example, a tungsten layer or a molybdenum layer formed by chemical vapor deposition (CVD) or the like, and is an example of a first metal layer. As described later, the conductive layer 24 included in the contacts CG and CS is, for example, a tungsten layer or a molybdenum layer formed by atomic layer deposition (ALD) or the like, and is an example of a second metal layer.

The oxidized silicide layers 22 and 21 respectively included in the contacts CG and CS are, for example, TiSiOx layers containing Ti as a metal, the oxidized silicide layer 22 included in the contact CG is an example of a third oxidized silicide layer, and the oxidized silicide layer 21 included in the contact CS is an example of first and second oxidized silicide layers.

However, a part or all of oxygen contained in the oxidized silicide layers 21 and 22 does not have to be chemically bonded to Ti or the like in the oxidized silicide layers 21 and 22, and the oxidized silicide layers 21 and 22 that are TiSiOx layers or the like do not have to be silicide oxides in a chemical sense. Thus, the oxidized silicide layers 21 and 22 have conductivity, and the conductive layers 23 and 24 of the contacts CG and CS can be electrically connected to the gate electrode GT and the source/drain regions 31 via the oxidized silicide layers 22 and 21 and the silicide layers 33 and 32, respectively.

### (Method for Manufacturing Semiconductor Device)

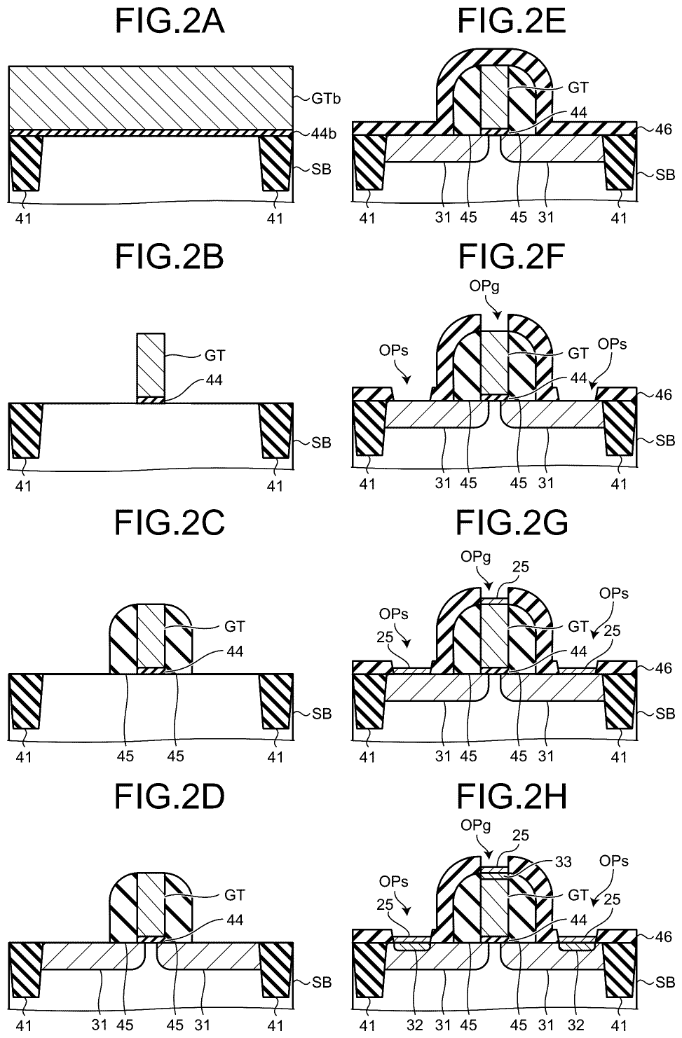

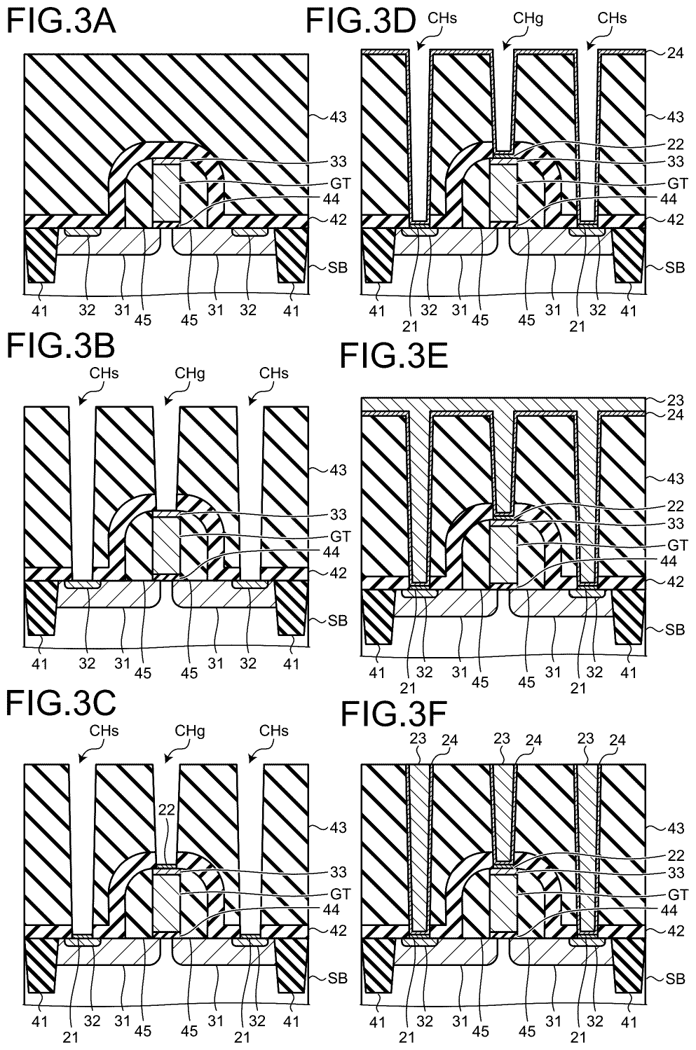

Next, a method for manufacturing the semiconductor device 1 according to an embodiment will be described with reference to FIGS. 2A to 4F. FIGS. 2A to 3F are cross-sectional views sequentially exemplifying a part of a procedure of the method for manufacturing the semiconductor device 1 according to the embodiment.

As illustrated in FIG. 2A, silicon oxide layers or the like are embedded in the semiconductor substrate SB to form the element isolation layers 41 that partition the semiconductor substrate SB. In addition, a gate insulating layer 44b such as a silicon oxide layer and a gate electrode layer GTb such as a polysilicon layer are formed in this order on the semiconductor substrate SB. The gate insulating layer 44b and the gate electrode layer GTb are layers before being formed into a predetermined shape, and cover the entire semiconductor substrate SB.

As illustrated in FIG. 2B, the gate electrode layer GTb and the gate insulating layer 44b are processed into predetermined shapes by, for example, plasma etching or the like, and the gate electrode GT and the gate insulating layer 44 are formed in a region of the semiconductor substrate SB partitioned by the element isolation layers 41.

As illustrated in FIG. 2C, the spacer layers 45 are formed that cover side surfaces of the gate electrode GT and the gate insulating layer 44. The spacer layers 45 are formed by forming a silicon oxide layer or the like that covers the entire gate electrode GT and gate insulating layer 44 and etching back the silicon oxide layer or the like.

As illustrated in FIG. 2D, impurities of a predetermined conductivity type are injected into a region of the semiconductor substrate SB partitioned by the element isolation layers 41 and on which the gate electrode GT and the like are formed, and further diffused into the semiconductor substrate SB by annealing treatment. At this time, since the spacer layers 45 prevent the injection of the impurities directly below the gate electrode GT, the impurities are not injected directly below the gate electrode GT and gate insulating layer 44, and the source/drain regions 31 separated by a predetermined distance are formed on both sides of the gate electrode GT. Such a method for forming the source/drain regions 31 is also referred to as a self-alignment method.

As illustrated in FIG. 2E, the gate electrode GT, the gate insulating layer 44, and the spacer layers 45, and a protective layer 46 that covers an upper surface of the semiconductor substrate SB are formed. The protective layer 46 is, for example, a silicon oxide layer or the like, and functions as a silicide block layer that prevents formation of a silicide layer in a region other than a desired region when the silicide layers 32 and 33 described below are formed.

As illustrated in FIG. 2F, the protective layer 46 is etched to form openings OPg and OPs on an upper surface of the gate electrode GT and partial surfaces of the source/drain regions 31, respectively.

As illustrated in FIG. 2G, metal layers 25 such as NiPt layers are formed in the openings OPg and OPs of the protective layer 46 by, for example, physical vapor deposition (PVD) or the like.

As illustrated in FIG. 2H, the silicide layers 33 and 32 such as NiPtSi layers are formed on the upper surface of the gate electrode GT and the partial surfaces of the source/drain regions 31, which are covered with the metal layers 25, by performing annealing treatment or the like. The silicide layers 33 and 32 are formed by Ni and the like in the metal layer 25 that serves as diffusion species and entering silicon forming the gate electrode GT and the source/drain regions 31.

After the silicide layers 32 and 33 are formed, the metal layers 25 and the protective layer 46 are removed.

As illustrated in FIG. 3A, the silicide layer 33, the gate electrode GT, the gate insulating layer 44, and the spacer layers 45, and the liner layer 42 that covers the upper surface of the semiconductor substrate SB are formed, and the insulating layer 43 that covers the liner layer 42 is further formed.

As illustrated in FIG. 3B, contact holes CHg and CHs that penetrate the insulating layer 43 and respectively reach the silicide layer 33 on the gate electrode GT and the silicide layers 32 on upper surfaces of the source/drain regions 31 are formed. The contact hole CHg that reaches the silicide layer 33 on the gate electrode GT is an example of a third through hole. The contact holes CHs that respectively reach the silicide layers 32 on the upper surfaces of the source/drain regions 31 are examples of first and second through holes.

As illustrated in FIG. 3C, the oxidized silicide layers 22 and 21 such as TiSiOx layers are formed at lower end portions of the contact holes CHg and CHs, respectively. Details of a method for forming the oxidized silicide layers 22 and 21 will be described later.

As illustrated in FIG. 3D, the conductive layer 24 is formed such as a tungsten layer or a molybdenum layer that covers bottom surfaces and side surfaces of the contact holes CHg and CHs. The conductive layer 24 is also formed on an upper surface of the insulating layer 43. Note that, at this time, the conductive layer 24 can be formed with good coverage in the contact holes CHg and CHs having high aspect ratios by using ALD or the like.

As illustrated in FIG. 3E, the contact holes CHg and CHs are filled with the conductive layer 23 such as a tungsten layer or a molybdenum layer via the conductive layer 24. The conductive layer 23 is also formed on the upper surface of the insulating layer 43 via the conductive layer 24.

As illustrated in FIG. 3F, the conductive layers 23 and 24 on the upper surface of the insulating layer 43 are removed by chemical mechanical polishing (CMP) or the like. As a result, the contacts CG and CS are formed that are respectively connected to the gate electrode GT and the source/drain regions 31 via the silicide layers 33 and 32. In the method of manufacturing the semiconductor device 1, the conductive layer 23 is an example of a second metal layer, and the conductive layer 24 is an example of a first metal layer.

As described above, the semiconductor device 1 of the embodiment is manufactured.

Here, the method for forming the oxidized silicide layers 22 and 21 at lower end portions of the contacts CG and CS will be described in detail.

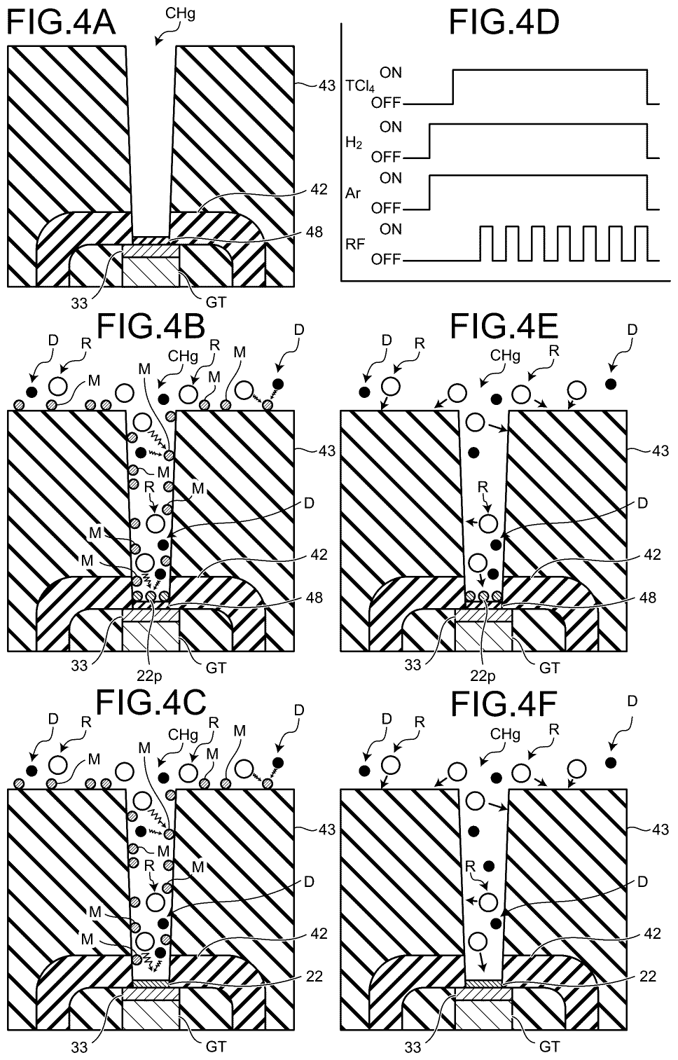

FIGS. 4A to 4F are diagrams illustrating an example of a procedure of the method for forming the oxidized silicide layer 22 included in the semiconductor device 1 according to the embodiment. More specifically, FIG. 4A is a cross-sectional view illustrating a state of the silicide layer 33 formed on the gate electrode GT. FIG. 4D is a timing chart illustrating a part of the method for forming the oxidized silicide layer 22. FIGS. 4C, 4E, and 4F are cross-sectional views illustrating a state in which the oxidized silicide layer 22 is formed on the silicide layer 33 on the upper surface of the gate electrode GT.

As illustrated in FIG. 4A, after the silicide layer 33 is formed on the gate electrode GT, the semiconductor substrate SB is exposed to the atmosphere for a predetermined time, so that a surface of the silicide layer 33 may be naturally oxidized to form an oxide layer 48 such as a silicon oxide (SiOx) layer.

As illustrated in FIG. 4D, the oxidized silicide layer 22 such as a TiSiOx layer is formed by intermittently treating the inside of the contact hole CHg in the above-described state with plasma of a metal halide gas such as TiCl₄ gas.

More specifically, a reaction gas such as H₂ gas for performing a decomposition reaction with a metal halide in the plasma of the metal halide gas and a rare gas such as Ar gas that serves as a dilution gas are supplied to the semiconductor substrate SB, and a periphery of the semiconductor substrate SB is adjusted to a desired pressure. Thereafter, the metal halide gas such as the TiCl₄ gas is further supplied to the semiconductor substrate SB.

In addition, radio frequency power (resonant frequency (RF)) is applied to the metal halide gas, the reaction gas, and the dilution gas for a predetermined time, and then supply of the radio frequency power is stopped for a predetermined time. In this manner, application and supply stop of the radio frequency power for respective predetermined times are repeated a predetermined number of times.

As described above, the oxidized silicide layer 22 is formed by, for example, intermittent plasma-CVD using the metal halide gas. Hereinafter, a case will be described where the TiCl₄ gas is used as the metal halide gas and the H₂ gas is used as the reaction gas.

As illustrated in FIG. 4B, the radio frequency power is applied to a TiCl₄ gas R and the like, whereby plasma of these gases is generated. TiCl₄ in the TiCl₄ gas R that is turned into plasma and has increased reactivity is adsorbed to a surface of the oxide layer 48 on the bottom surface of the contact hole CHg, a surface of the insulating layer 43 on the side surface of the contact hole CHg, and the like. H₂ in the H₂ gas D that is turned into plasma and has increased reactivity reacts with TiCl₄ to decompose TiCl₄.

Ti of TiCl₄ decomposed by H₂ is deposited on the insulating layer 43 on the side surface of the contact hole CHg, and a thin layer M of Ti is formed. The thin layer M of Ti is also formed on the upper surface of the insulating layer 43. On the oxide layer 48 on the bottom surface of the contact hole CHg, Ti of TiCl₄ decomposed by H₂ reacts with the oxide layer 48 that is a SiOx layer or the like, and a thin layer 22p of TiSiOx is formed.

As illustrated in FIG. 4E, when the supply of the radio frequency power to the TiCl₄ gas R or the like is stopped, the TiCl₄ gas R remains partially undecomposed around the semiconductor substrate SB including the inside of the contact hole CHg. Since the TiCl₄ gas R that is the undecomposed TiCl₄ gas R and is activated by heat has corrosiveness, the thin layer M of Ti formed on the side surface of the contact hole CHg and the upper surface of the insulating layer 43 is etched away. At this time, an active Cl₂ gas or the like generated by decomposition of a part of the TiCl₄ gas R may contribute to etching of the thin layer M. On the other hand, the thin layer 22p of TiSiOx on the bottom surface of the contact hole CHg remains without being removed by the TiCl₄ gas R or the like.

As illustrated in FIG. 4C, the radio frequency power is applied again to the TiCl₄ gas R or the like, whereby the thin layer M of Ti is newly formed on the side surface of the contact hole CHg and the upper surface of the insulating layer 43. At the bottom surface of the contact hole CHg, the oxide layer 48 is further reduced by reaction between the oxide layer 48 and Ti to be replaced with the oxidized silicide layer 22 such as a TiSiOx layer.

As illustrated in FIG. 4F, when the supply of the radio frequency power to the TiCl₄ gas R or the like is stopped again, the thin layer M of Ti on the side surface of the contact hole CHg and the upper surface of the insulating layer 43 is removed by the active TiCl₄ gas R or the like. The oxidized silicide layer 22 on the bottom surface of the contact hole CHg remains without being removed by the undecomposed TiCl₄ gas R.

As described above, the oxidized silicide layer 22 having a desired thickness is selectively formed on the silicide layer 33 on the bottom surface of the contact hole CHg without formation of a Ti layer or the like on the side surface of the contact hole CHg and the upper surface of the insulating layer 43 by intermittent plasma-CVD that repeats the application and supply stop of the radio frequency power to the TiCl₄ gas R or the like.

At this time, a ratio (duty ratio) of an application time of the radio frequency power to a stop time is preferably less than or equal to 0.25. That is, when a total of the application time and the stop time of the radio frequency power is 1, it is desirable that the ratio of the application time does not exceed 0.2. This makes it possible to reduce the oxide layer 48 on the bottom surface of the contact hole CHg while more reliably suppressing formation of a Ti layer or the like on the side surface of the contact hole CHg and the upper surface of the insulating layer 43.

Note that the oxide layer 48 described above can also be formed on upper surfaces of the silicide layers 32 on the source/drain regions 31. Thus, formation of the oxidized silicide layer 21 on the upper surfaces of the silicide layers 32 on the source/drain regions 31, which is performed in parallel with formation of the oxidized silicide layer 22 on the upper surface of the silicide layer 33 on the gate electrode GT, is also performed similarly to FIGS. 4A to 4F described above.

### SUMMARY

In order to speed up operation of a transistor, a technique has been developed of connecting a contact to the transistor via a silicide layer such as a NiPtSi layer. An oxide layer may be formed on a surface of the silicide layer by natural oxidation, and contact resistance increases.

Thus, a method may be adopted for reducing the oxide layer on the surface of the silicide layer by a Ti layer by forming the Ti layer on a bottom surface and a side surface of a contact hole by plasma-CVD or the like using a TiCl₄ gas or the like. At this time, in order to suppress aggregation of the silicide layer such as the NiPtSi layer, the plasma-CVD using the TiCl₄ gas or the like is performed at a low temperature.

For this reason, the Ti layers formed on the bottom surface and the side surface of the contact hole contain chlorine derived from the TiCl₄ gas at a high concentration. Thus, nitriding of the formed Ti layer is performed, and further, a TiN layer is formed by ALD or the like, whereby corrosion is suppressed of a tungsten layer or the like filling the contact hole thereafter.

As a result, the contact has a barrier metal layer such as the TiN layer with a high resistance, and such a barrier metal layer itself may cause an increase in contact resistance. In addition, a volume of the tungsten layer with a low resistance or the like that serves as a core material of the contact is compressed by the thick barrier metal layer, and it becomes more difficult to reduce the contact resistance.

According to the semiconductor device 1 of the embodiment, the contacts CG and CS include: the oxidized silicide layers 22 and 21 that are disposed at respective lower end portions and contain a metal such as Ti different from the silicide layers 33 and 32; and metal layers that each extend in the insulating layer 43 so as to be in contact with the insulating layer 43 at side surfaces.

As described above, by forming the contacts CG and CS without providing the barrier metal layer with the high resistance, it is possible to suppress an increase in contact resistance due to the barrier metal layer. In addition, volumes of the conductive layers 23 and 24 that serve as the core materials of the contacts CG and CS can be increased, and further, the contact resistance can be reduced.

According to the method for manufacturing the semiconductor device 1 of the embodiment, the contact holes CHg and CHs are intermittently treated with the plasma of the metal halide gas, and the oxidized silicide layers 22 and 21 containing a metal, such as Ti different from the silicide layers 33 and 32, derived from the metal halide gas, are formed on the bottom surfaces of the contact holes CHg and CHs, respectively. Thus, the contacts CG and CS can be formed without providing the barrier metal layer with the high resistance.

According to the method for manufacturing the semiconductor device 1 of the embodiment, the metal such as Ti in the metal halide gas is deposited on the silicide layers 33 and 32 and the side surfaces of the contact holes CHg and CHs by applying the radio frequency power to the metal halide gas supplied to the contact holes CHg and CHs. In addition, the metal such as Ti deposited on the side surfaces of the contact holes CHg and CHs is removed by stopping supply of the radio frequency power while continuing supply of the metal halide gas.

As described above, by using the intermittent plasma-CVD that alternately repeats deposition and etching removal of the Ti layer, it is possible to reduce the surfaces of the silicide layers 33 and 32 at the lower end portions of the contact holes CHg and CHs without forming the Ti layer or the like on the side surface of the contact holes CHg and CHs.

According to the method for manufacturing the semiconductor device 1 of the embodiment, depositing the metal such as Ti on the silicide layers 33 and 32 includes reducing the oxide layer 48 by natural oxidation formed on the surfaces of the silicide layers 33 and 32 with the metal such as Ti. As a result, the contact resistance can be reduced.

### (Application Example)

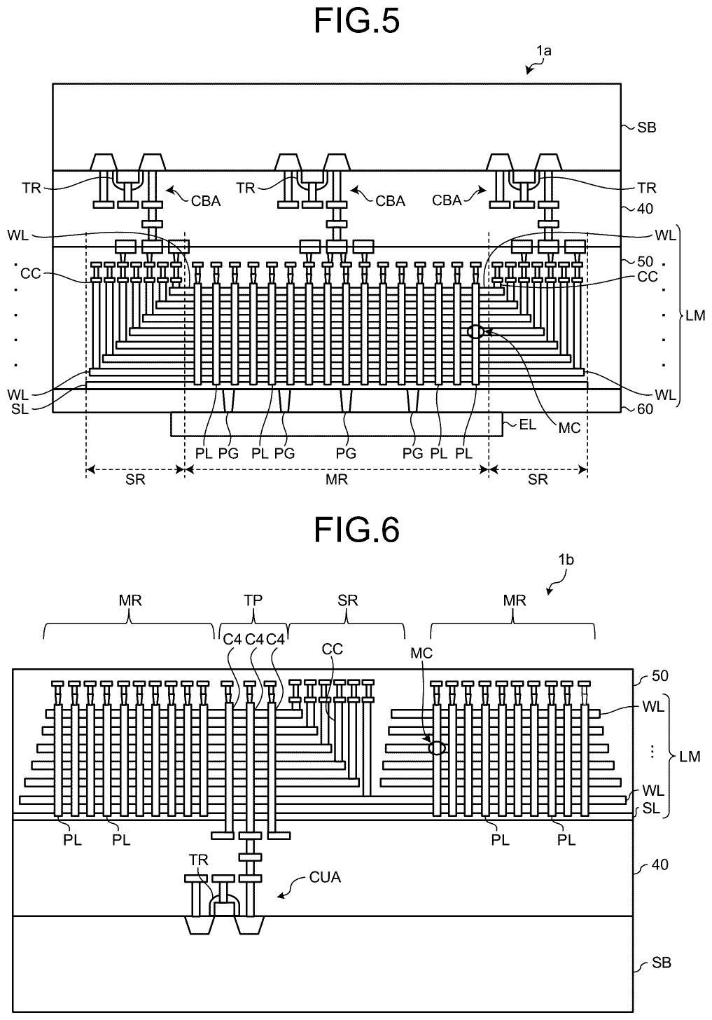

Next, an application example of the transistor TR of the embodiment will be described with reference to FIGS. 5 and 6. The transistor TR, and the contacts CS and CG respectively including the oxidized silicide layers 22 and 21 at the lower end portions of the embodiment described above can be applied to, for example, a three-dimensional nonvolatile memory or the like illustrated in FIGS. 5 and 6.

FIG. 5 is a cross-sectional view illustrating an example of a semiconductor device 1a to which the transistor TR according to the embodiment is applied. However, hatching is omitted in FIG. 5 in consideration of visibility of the drawing.

As illustrated in FIG. 5, the semiconductor device 1a includes, in order from the lower side of the drawing, an electrode film EL, a source line SL, and a stacked body LM in which a plurality of word lines WL is stacked. In addition, the semiconductor device 1a includes a peripheral circuit CBA provided on the semiconductor substrate SB above the stacked body LM.

The source line SL is disposed on the electrode film EL with an insulating layer 60 interposed therebetween. The source line SL is, for example, a polysilicon layer or the like.

A plurality of plugs PG is disposed in the insulating layer 60, and the source line SL and the electrode film EL maintain electrical conduction via the plugs PG. As a result, a source potential can be applied to the source line SL from the outside of the semiconductor device 1a via the electrode film EL and the plugs PG.

On the source line SL, the stacked body LM is disposed in which the word lines WL as a plurality of conductive layers are stacked one by one while being separated from each other. A memory region MR is disposed in a central portion of the stacked body LM, and staircase regions SR are disposed at both end portions of the stacked body LM.

In the memory region MR, a plurality of pillars PL is disposed penetrating the stacked body LM in a stacking direction. A plurality of memory cells MC is formed at intersections of the pillars PL and the word lines WL. As a result, the semiconductor device 1a is configured as, for example, a three-dimensional nonvolatile memory in which the memory cells MC are three-dimensionally disposed in the memory region MR.

In the staircase region SR, the plurality of word lines WL is processed in a staircase shape and terminated. At this time, as a distance from the memory region MR increases, the plurality of word lines WL forming terrace portions moves from an upper layer side to a lower layer side, so that a height position of the terrace portions falls toward the source line SL side.

Contacts CC connected to the word lines WL of respective layers are disposed in the terrace portions of respective steps formed by the plurality of word lines WL, respectively. The word lines WL and the like stacked in multiple layers are individually drawn out by these contacts CC.

More specifically, write voltages, read voltages, and the like are applied from these contacts CC to the memory cells MC included in the memory region MR in the central portion of the plurality of word lines WL via the word lines WL at the same height positions as the memory cells MC.

The plurality of word lines WL, the pillars PL, and the contacts CC are covered with an insulating layer 50. The insulating layer 50 also extends around these components.

On the surface of the semiconductor substrate SB above the insulating layer 50, the peripheral circuit CBA is disposed including the transistor TR, the contacts CG and CS (see FIG. 1), and the like of the embodiment described above. Various voltages applied from the contacts CC to the memory cells MC are controlled by the peripheral circuit CBA electrically connected to these contacts CC. As a result, the peripheral circuit CBA controls electrical operation of the memory cells MC.

The peripheral circuit CBA is covered with an insulating layer 40, and the insulating layer 40 and the insulating layer 50 that covers the plurality of word lines WL and the like are joined together to form the semiconductor device 1a including components such as the stacked body LM, the pillars PL, and the contacts CC, and the peripheral circuit CBA.

Note that the insulating layer 43 described above (see FIG. 1) that covers the transistor TR and the like forms a part of the insulating layer 40 that covers the peripheral circuit CBA.

FIG. 6 is a cross-sectional view illustrating an example of another semiconductor device 1b to which the transistor TR according to the embodiment is applied. However, hatching is omitted in FIG. 6 in consideration of visibility of the drawing.

As illustrated in FIG. 6, the semiconductor device 1b includes the semiconductor substrate SB, a peripheral circuit CUA disposed on the semiconductor substrate SB, and the stacked body LM in which the plurality of word lines WL is stacked one by one while being separated from each other.

The peripheral circuit CUA includes the transistor TR, the contacts CS and CG (see FIG. 1), and the like of the embodiment described above. The peripheral circuit CUA including the transistor TR and the like is covered with the insulating layer 40. Note that the insulating layer 43 described above (see FIG. 1) that covers the transistor TR and the like forms a part of the insulating layer 40 that covers the peripheral circuit CUA.

The stacked body LM is disposed above the source line SL provided on the insulating layer 40 that covers the peripheral circuit CUA. In addition, the stacked body LM includes the staircase region SR in the central portion, and the memory regions MR on both sides of the staircase region SR. In addition, the stacked body LM is provided with a through contact region TP close to the staircase region SR.

In the memory region MR, a plurality of pillars PL is disposed penetrating the stacked body LM in a stacking direction. A plurality of memory cells MC is formed at intersections of the pillars PL and the word lines WL. As a result, the semiconductor device 1b is also configured as, for example, a three-dimensional nonvolatile memory in which the memory cells MC are three-dimensionally disposed in the memory region MR.

In the staircase region SR, the plurality of word lines WL of the stacked body LM is processed in a staircase shape, and have a rectangular mortar shape in a top view. In one side of the mortar shape, the contact CC is connected on a terrace of each of the word lines WL processed in a staircase shape.

Each of the plurality of contacts CC is connected to a plurality of contacts C4 provided in the through contact region TP via upper layer wiring and a plug. The plurality of contacts C4 penetrates the stacked body LM and the source line SL, and reach the insulating layer 40 below the stacked body LM. In the insulating layer 40, a lower end portion of each of the plurality of contacts C4 is connected to the transistor TR of the peripheral circuit CUA via lower layer wiring, a via, contacts CG and CS, and the like.

With such a configuration, by applying a predetermined voltage from the peripheral circuit CUA to each memory cell MC via the contacts C4 and CC, it is possible to electrically operate the memory cell MC.

As described above, the transistor TR, the contacts CS and CG, and the like of the embodiment described above can be applied to the peripheral circuits CBA and CUA that control the electrical operation of the memory cell MC, for example, in a semiconductor memory device such as a three-dimensional nonvolatile memory.

As described above, the semiconductor memory device including the peripheral circuits CBA and CUA can include, for example, the stacked body LM and the pillars PL, and the peripheral circuits CBA and CUA are disposed, for example, above or below the stacked body LM. In addition, the staircase region SR for electrically drawing out the plurality of stacked word lines WL can be disposed at an end portion, a central portion, or the like of the stacked body LM.

As described above, the semiconductor memory device including the peripheral circuits CBA and CUA can adopt various configurations.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
first and second regions that are provided in a substrate and disposed apart from each other in a first direction that extends along the substrate, the first and second regions containing impurities of a first conductivity type;
a gate electrode disposed above the substrate between the first and second regions;
first and second metal silicide layers disposed in the first and second regions, respectively; and
first and second contacts connected to the first and second regions via the first and second metal silicide layers, respectively, wherein
the first and second contacts include:
first and second oxidized silicide layers that are disposed at lower end portions of the first and second contacts and contain a predetermined metal different from metals included in the first and second metal silicide layers, respectively; and
metal layers that are in contact with the first and second oxidized silicide layers and extend in a second direction that intersects the first direction, respectively.

2. The semiconductor device according to claim 1, further comprising
an insulating layer that covers the gate electrode, the first and second regions, and the first and second metal silicide layers, wherein
the metal layers of the first and second contacts each include:
a first metal layer that serves as a core material of the first and second contacts; and
a second metal layer that covers a bottom surface and a side surface of the first metal layer.

3. The semiconductor device according to claim 1, further comprising
an insulating layer that covers the gate electrode, the first and second regions, and the first and second metal silicide layers;
a third metal silicide layer disposed on an upper surface of the gate electrode; and
a third contact that penetrates the insulating layer and is connected to the gate electrode via the third metal silicide layer, wherein
the third contact includes:
a third oxidized silicide layer that is disposed at a lower end portion of the third contact and contains the predetermined metal; and
a metal layer that extends in the insulating layer to be in contact with the insulating layer on a side surface.

4. The semiconductor device according to claim 3, wherein
the metal layer of the third contact includes:
a first metal layer that serves as a core material of the third contact; and
a second metal layer that covers a bottom surface and a side surface of the first metal layer.

5. The semiconductor device according to claim 1, wherein
the first and second metal silicide layers each include a NiPtSi layer.

6. The semiconductor device according to claim 1, wherein
the first and second oxidized silicide layers each include a TiSiOx layer.

7. The semiconductor device according to claim 2, wherein
the first metal layer includes a tungsten layer or a molybdenum layer, and
the second metal layer includes a tungsten layer or a molybdenum layer.

8. The semiconductor device according to claim 1, further comprising
a stacked body in which a plurality of conductive layers are stacked one by one while being separated from each other;
a semiconductor pillar that extends in a stacking direction of the stacked body; and
a peripheral circuit, wherein
the peripheral circuit includes the first and second regions and the gate electrode.

9. The semiconductor device according to claim 8, wherein
the peripheral circuit is disposed above the stacked body and the semiconductor pillar.

10. The semiconductor device according to claim 8, wherein
the peripheral circuit is disposed below the stacked body and the semiconductor pillar.

11. A method for manufacturing a semiconductor device, the method comprising:
forming first and second regions containing impurities of a first conductivity type in a substrate while separating the first and second regions from each other in a first direction that extends along the substrate;
forming a gate electrode above the substrate between the first and second regions;
forming first and second metal silicide layers in the first and second regions, respectively;
forming an insulating layer that covers the gate electrode, the first and second regions, and the first and second metal silicide layers;
forming first and second holes that penetrate the insulating layer and reach the first and second metal silicide layers, respectively;
forming first and second oxidized silicide layers on bottom surfaces of the first and second holes by treating the first and second holes with plasma of a metal halide gas, respectively, the metal halide gas containing a metal that is different from metals included in the first and second metal silicide layers; and
forming first and second contacts in the first and second holes by filling the first and second holes with a metal layer, respectively.

12. The method for manufacturing a semiconductor device according to claim 11, wherein
treating the first and second holes with the plasma includes alternately repeating:
supplying the metal halide gas to the first and second holes while applying radio frequency power to the metal halide gas; and
stopping application of the radio frequency power while continuing supply of the metal halide gas.

13. The method for manufacturing a semiconductor device according to claim 12, wherein
the radio frequency power is applied to deposit the metal contained in the metal halide gas on the first and second metal silicide layers and side surfaces of the first and second holes, and
application of the radio frequency power is stopped to remove the metal deposited on the side surfaces of the first and second holes.

14. The method for manufacturing a semiconductor device according to claim 13, wherein
depositing the metal on the first and second metal silicide layers includes reducing a natural oxide layer formed on surfaces of the first and second metal silicide layers with the metal.

15. The method for manufacturing a semiconductor device according to claim 11, wherein
filling the first and second holes with the metal layer includes:
and
forming, in each of the first and second holes, a first metal layer that covers first and second oxidized silicide layers and side surfaces of the first and second holes; and
forming a second metal layer on the first metal layer, the second metal layer serving as a core material.

16. The method for manufacturing a semiconductor device according to claim 11, further comprising
forming a third metal silicide layer on an upper surface of the gate electrode,
forming a third hole that penetrates the insulating layer and reaches the third metal silicide layer,
forming a third oxidized silicide layer on a bottom surface of the third hole by treating the third hole with the plasma, and
forming a third contact by filling the third hole with a metal layer.

17. The method for manufacturing a semiconductor device according to claim 16, wherein
filling the third hole with the metal layer includes:
forming, in the third hole, a first metal layer that covers the third oxidized silicide layer and a side surface of the third hole
forming, in the third hole, a second metal layer on the first metal layer, the second metal layer serving as a core material of the third contact.

18. The method for manufacturing a semiconductor device according to claim 11, wherein
the first and second metal silicide layers each include a NiPtSi layers.

19. The method for manufacturing a semiconductor device according to claim 11, wherein
the first and second oxidized silicide layers each include a TiSiOx layer.

20. The method for manufacturing a semiconductor device according to claim 15, wherein
the first metal layer includes a tungsten layer or a molybdenum layer, and
the second metal layer includes a tungsten layer or a molybdenum layer.
